(19) United States
(12) Patent Application Publication
(10) Pub. No.: US 2014/0124521 A1
(43) Pub. Date: May 8, 2014

(54) RETRACTABLE HANDLE FOR ELECTRONIC DEVICES AND PROTECTIVE CASES AND METHOD OF USE

(71) Applicant: Michael L. Brown, Cottonwood Heights, UT (US)

(72) Inventor: Michael L. Brown, Cottonwood Heights, UT (US)

(21) Appl. No.: 14/072,854

(22) Filed: Nov. 6, 2013

Related U.S. Application Data
(60) Provisional application No. 61/722,908, filed on Nov. 6, 2012.

(51) Int. Cl. B65D 25/28; H05K 5/03

(52) U.S. Cl. CPC B65D 25/28; H05K 5/03
USPC 220/756; 220/761

(57) ABSTRACT

In one embodiment, a protective case comprises at least one retractable handle and a means for extending the handle. The means for extending the handle comprising a pull-tab, tab-locks, hooks, or button releasing mechanisms known to those of skill in the art.

In another embodiment, the protective case comprises a retractable handle, a means for extending the handle, coil springs or their equivalents, and a means for securing the handle in the retracted position.

### CROSS-REFERENCE TO RELATED APPLICATIONS

This application claims the benefit of U.S. Provisional Application Ser. No. 61/722,908, filed on Nov. 06, 2012, and is incorporated herein by reference.

### TECHNICAL FIELD

The present technology relates to electronic devices and their cases. More particularly, the present technology relates to a retractable handle for cell phones, tablets, and other electronic devices and their cases.

### BACKGROUND

A common problem when using a cell phone, tablet, or other portable electronic device to take pictures, video, play games, and the like, is the inability of the user to firmly grip the phone. Many devices are touch-screens, or otherwise have large screens, that make them impractical for gripping. Even when a device can be gripped, this often blocks the camera lens, creating unwanted pictures and video. The inability to properly grip the device leads to a higher risk of the device falling and breaking, or being stolen from one's hands while in use. The present invention seeks to solve these and other problems.

### SUMMARY OF EXAMPLE EMBODIMENTS

In one embodiment, a protective case comprises at least one retractable handle and a means for extending the handle. The means for extending the handle comprising a pull-tab, tab-locks, hooks, or button releasing mechanisms known to those of skill in the art.

In another embodiment, the protective case comprises a retractable handle, a means for extending the handle, coil springs or their equivalents, and a means for securing the handle in the retracted position. The means for securing the handle comprising tab-locks, hooks, buttons, or other mechanisms known to those with skill in the art.

In another embodiment, the protective case comprises an attachment, blockage, or other means to prohibit the handle from being extended beyond a maximum position.

In another embodiment, the retractable handle may further comprise an extendable support leg to create a stand for an electronic device.

In yet another embodiment, the housing of an electronic device comprises at least one retractable handle.

### BRIEF DESCRIPTION OF THE DRAWINGS

FIG. 1 is a perspective view of a cell phone case having a handle that extends from the side

FIG. 2 is a perspective view of a cell phone case having a handle that extends from the top

FIG. 3 is a perspective view of a cell phone case having a handle with a hook

FIG. 4 is a perspective view of a cell phone case having a handle with locking side-tabs

FIG. 5 is a cross-sectional view of a cell phone case having a handle that extends linearly within the case, is connected to a spring system, and has locking side tabs

FIG. 6 is a cross-sectional view of a cell phone case having a continuous handle within the case, is connected to a spring system, and has locking side tabs

FIG. 8 is a cross-sectional view of a cell phone case having an inner handle portion that slides within a channel

FIG. 9A is a side elevation view of a cell phone case having a handle with an extendable support leg

FIG. 9B is a perspective view of a handle with an extendable support leg

FIG. 9C is a perspective view of a handle with an extendable support leg with a locking leg

### DETAILED DESCRIPTION OF EXAMPLE EMBODIMENTS

The following descriptions depict only example embodiments and are not to be considered limiting of its scope. Any reference herein to “the invention” is not intended to restrict or limit the invention to exact features or steps of any one or more of the exemplary embodiments disclosed in the present specification. References to “one embodiment,” “an embodiment,” “various embodiments,” and the like, may indicate that the embodiment(s) so described may include a particular feature, structure, or characteristic, but not every embodiment necessarily includes the particular feature, structure, or characteristic. Further, repeated use of the phrase “in one embodiment,” or “in an embodiment,” do not necessarily refer to the same embodiment, although they may.

Accordingly, the particular arrangements disclosed are meant to be illustrative only and not limiting as to the scope of the invention, which is to be given the full breadth of the appended claims and any and all equivalents thereof. Moreover, many embodiments, such as adaptations, variations, modifications, and equivalent arrangements, will be implicitly disclosed by the embodiments described herein and fall within the scope of the present invention. Although specific terms are employed herein, they are used in a generic and descriptive sense only and not for purposes of limitation. Unless otherwise expressly defined herein, such terms are intended to be given their broad ordinary and customary meaning not inconsistent with that applicable in the relevant industry and without restriction to any specific embodiment hereinafter described. As used herein, the article “a” is intended to include one or more items. When used herein to join a list of items, the term “or” denotes at least one of the items, but does not exclude a plurality of items of the list. For exemplary methods or processes, the sequence and/or arrangement of steps described herein are illustrative and not restrictive.

It should be understood that the steps of any such processes or methods are not limited to being carried out in any particular sequence or arrangement. Indeed, the steps of the disclosed processes or methods generally may be carried out in various different sequences and arrangements while still falling within the scope of the present invention.

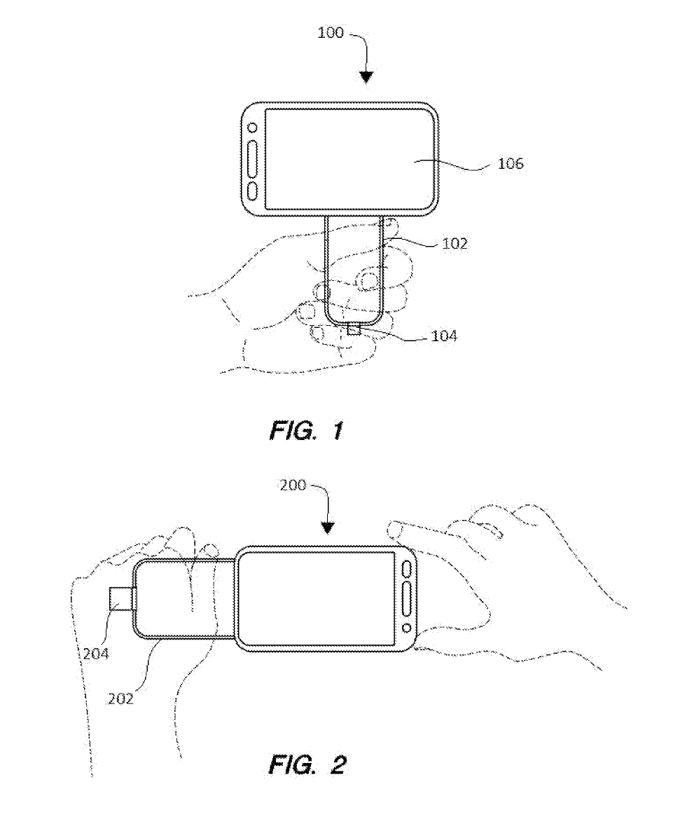

In one embodiment, as illustrated in FIG. 1, a protective case 100 (a housing for portable electronic devices) comprises a retractable handle 102 and a pull-tab 104 as means for extending the handle 102. When a user desires to have a better grip on the electronic device 106, such as a cell phone, a user extends retractable handle 102 by pulling outward on pull-tab 104. The user may then grip handle 102 to better secure the electronic device from the risk of damage or theft, or to aid the user in holding the device better for gameplay or other uses. Handle 102 may be made of metals, plastics, carbon fibers, or other substantially rigid materials. Further, handle 102 may be solid or may be a frame as illustrated in FIG. 1. Pull-tab 104 may be made from the same materials as the handle 102, but may also be made from cloths, rubbers, silicones, or any other material that a user may sufficiently grip so as to extend handle 102 from protective case 100. Further, protective case 100 may be from materials known to those in the industry, such as plastics, aluminums, rubbers, carbon fibers, etc.

As illustrated in FIG. 2, one embodiment shows a protective case 200 comprising retractable handle 202 and pull-tab 204 as a means of extending retractable handle 202. As FIG. 1 and FIG. 2 illustrate, retractable handles 102, 202 may extend laterally (perpendicularly), vertically (longitudinally), or at any other location that allows for retraction of the handle. While the figures only illustrate a protective case or housing having one handle, it will be appreciated that multiple handles may be used and would be beneficial for activities such as gameplay.

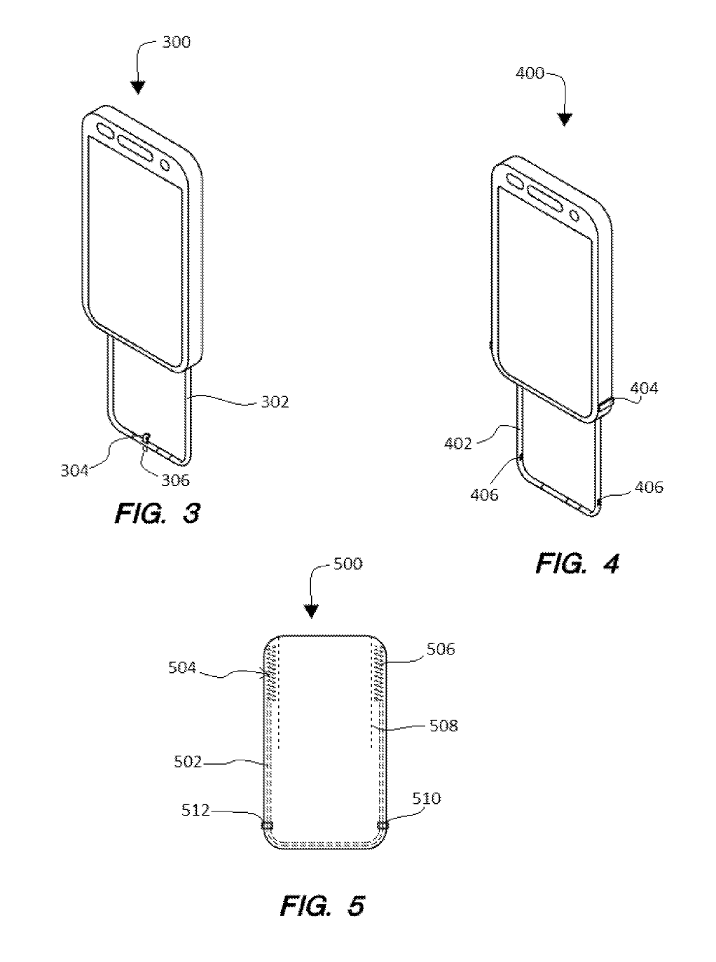

As illustrated in FIG. 3, a protective case 300 comprises a retractable handle 302 and a hook 304 as a securing device. When a user desires to use retractable handle 302, the user slides or pivots hook 304 using lever 306 to release the handle 302. A user may then pull on handle 302 to extend it to the desired position.

In another embodiment, as seen in FIG. 4, protective case 400 comprises retractable handle 402 and locking tabs 404 as a securing means. Locking tabs 404 engage handle apertures 406 to secure handle 402 within protective case 400. When a user desires to extend handle 402, a user presses locking tabs 404, which pivot and allow the inner portion of locking tabs 404 to disengage apertures 406, releasing the handle 402.

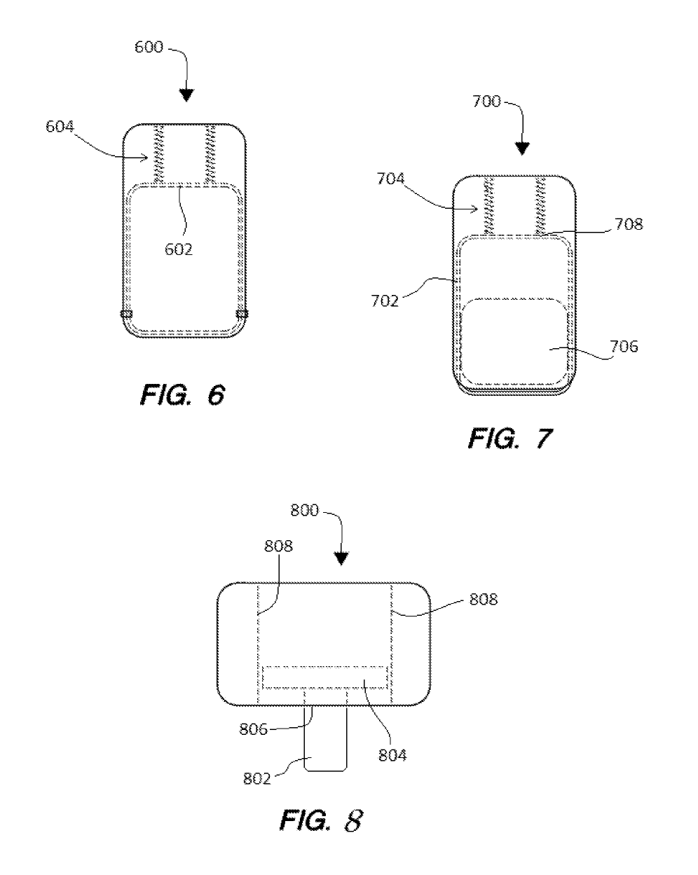

In yet another embodiment, as illustrated in FIG. 5, protective case 500 comprises retractable handle 502 and spring mechanisms 504. Spring mechanisms 504 may comprise coil springs 506 in a housing or channel 508 or equivalent means of keeping the springs in place during retraction and extension. Spring mechanisms 504 allow the handle 502 to easily extended when a securing mechanism, such as locking-tabs 510, are released by a user. For example, protective case 500 may have apertures 512 for engaging locking-tabs 510 on handle 502. A user pushes locking-tabs 510 through the apertures 512, allowing the coil springs 506 to extend, thereby extending handle 502 from within protective case 500. Further, it will be appreciated that handle 502 may be in the shape of a “U” as illustrated in FIG. 5, or, as more fully illustrated in FIG. 6, a retractable handle 602 may be of one continuous manufacture.

FIG. 6 further illustrates that spring mechanism 604 may be in alternate positions within a protective case as long as the same or similar result is achieved.

In another embodiment, as illustrated in FIG. 7, protective case 700 comprises retractable handle 702, spring mechanism 704, and restricting device 706. Restricting device 706 is an additional means of prohibiting full extension or withdrawal of the handle 702. Spring mechanisms 704 may comprise a first restricting means 708 such as solder, a weld, glue, or other means known to those of skill in the art. An additional restricting device 706 functions as a secondary restricting means. As illustrated, restricting device 706 comprises a solid section, such as plastic, rubber, or other suitable material, that is irremovably connected to case 700 or formed as a portion of case 700. This additional means assists in theft prevention if the user has a firm grip on handle 702. As a thief pulls on case 700, if the first restricting means 708 fail, secondary restricting means 706 prevent the handle from being withdrawn and released from the case 700.

FIG. 8 illustrates protective case 800 with a retractable handle 802. Retractable handle 802 has inner portion 804 that is larger than opening 806 of the protective case 800 so as to prevent the handle 802 from being fully removed from protective case 800. Further, inner portion 804 may fit inside of an inner channel or void created by walls 808 or may be sized so as to fit the dimensions of case 800.

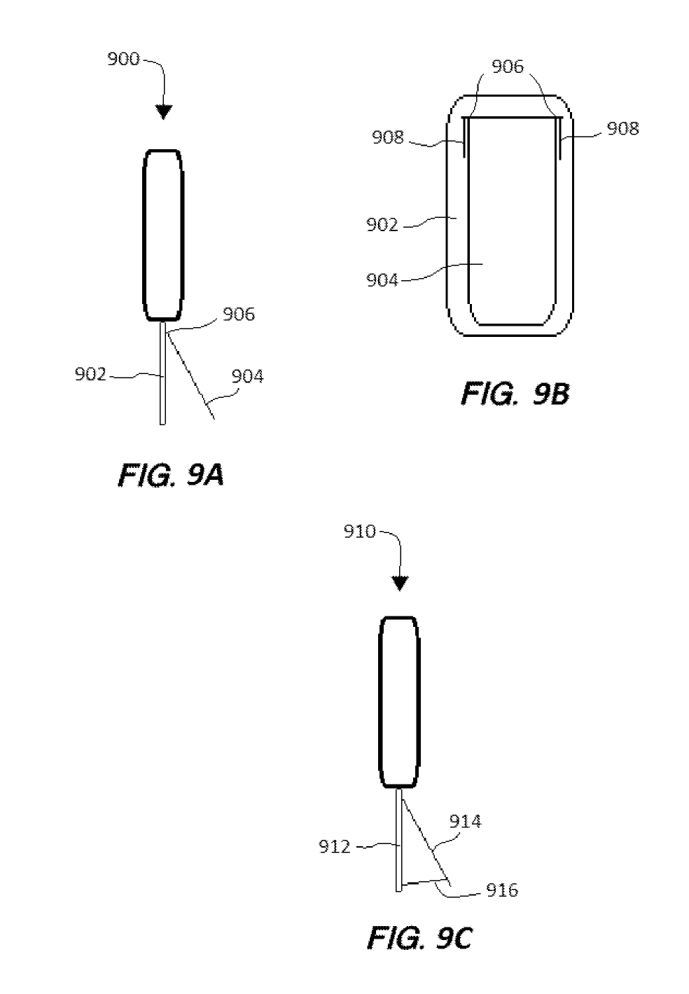

In FIG. 9A, protective case 900 illustrates a handle 902 having an extendable support leg 904. Extendable support leg 904 pivots at pivot points 906, as more fully illustrated in FIG. 9B. Therefore, a user desiring to have a hands-free stand for the electronic device may extend handle 902 from protective case 900, then extend support leg 904, which may slide vertically in a channel 908 and temporarily lock in place for added stability (or by other methods known to those in the art), and then rest the protective case and device on an appropriate surface.

As seen in FIG. 9C, protective case 910 may have retractable handle 912, extendable support leg 914, and locking leg 916. Locking leg 916 is pivotally attached to extendable support leg 914 and slides in grooves within retractable handle 912. A user desiring a stand may extend handle 912, extend support leg 914 by pulling outwardly, which allows locking leg 916 to slide down handle 912 into a position suitable for keeping extendable support leg 916 from collapsing. A suitable position may be when locking leg 916 is substantially horizontal or when it otherwise engages a stopping means, such as grooves, to hold it in place until released by a user.

In yet another embodiment of the present invention, the housing for an electronic device comprises a retractable handle. For example, a manufacturer of cell phones or tablet computers may manufacture the electronic device with the retractable handle built into the housing of the electronic device itself so that a user does not have to purchase an additional accessory, such as a protective case, to have the retractable handle.

What is claimed is:

1. A protective case for portable, hand-held electronics, comprising:
a housing;
a retractable handle within the housing;
a means for extending the handle; and
a means for restricting complete withdrawal of the handle.

2. The means for extending the handle of claim 1 wherein the means comprises an elongated handle, a pull-tab, tab-locks, hooks, or button releasing mechanisms.

3. The means for restricting complete withdrawal of the handle of claim 1 wherein the means comprises an attachment to the housing or a blockage.

4. The blockage of claim 3 wherein the blockage is comprised of plastics or rubbers and is permanently attached to the housing.

5. The means for restricting complete withdrawal of claim 1, wherein the handle has an inner portion sized larger than the handle opening in the housing.

6. The retractable handle of claim 1, wherein the handle extends perpendicularly from the protective case.

7. The retractable handle of claim 1, wherein the handle extends longitudinally from the protective case.

8. The retractable handle of claim 1 further comprising a support leg.

9. The support leg of claim 8 further comprising a locking leg.

10. A protective case for portable, hand-held electronics, comprising:
a housing;
a retractable handle within the housing;
spring mechanisms; and
a means for securing the handle in a retracted position.

11. The means for securing the handle of claim 10 comprising tab-locks, hooks, or button releasing mechanisms.

12. The spring mechanisms of claim 10 comprising at least one coil spring.

13. The at least one coil spring of claim 12 wherein the spring is permanently attached to the housing and the retractable handle.

14. The spring mechanisms of claim 10 wherein the housing further comprises channels for receiving coil springs.

15. The handle of claim 10 wherein the handle is a continuous handle in the shape of a square or rectangle.

16. The handle of claim 10 wherein the handle has an inner portion sized larger than the handle opening in the housing.

17. The retractable handle of claim 10 further comprising a support leg.

18. The support leg of claim 17 further comprising a locking leg.

19. A method of using a protective case with at least one retractable handle, the method comprising:
extending the at least one retractable handle from within the housing of a protective case; and
holding the handle to take pictures or video or otherwise view the display of the mobile device.

20. The method of using a protective case of claim 19 further comprising extending a support leg from the retractable handle and placing the mobile device on a surface.
